(19) United States
(12) Patent Application Publication
(10) Pub. No.: US 2015/0146367 A1
(43) Pub. Date: May 28, 2015

(54) CONTAINER DATA CENTER AND HEAT DISSIPATION SYSTEM

(71) Applicant: Hon Hai Precision Industry Co., Ltd., New Taipei (TW)

(72) Inventor: SHIH-CHIEH CHEN, New Taipei (TW)

(73) Assignee: HON HAI PRECISION INDUSTRY CO., LTD., New Taipei (TW)

(21) Appl. No.: 14/101,363

(22) Filed: Dec. 10, 2013

(30) Foreign Application Priority Data
Nov. 22, 2013 (TW) 102142735

(51) Int. Cl. H05K 7/20; F28F 27/02

(52) U.S. Cl. CPC H05K 7/20736; F28F 27/02
USPC 361/679.46; 165/96; 165/287

(57) ABSTRACT

A heat dissipation system includes a number of condensers, an air distribution apparatus, a number of guiding pipes, and a controller. The air distribution apparatus includes a distribution box and a number of adjusting members. The distribution box defines an air inlet and a number of air outlets arranged along a lengthwise direction of the distribution box. The adjusting members are rotatably installed in the air outlets of the distribution box. The guiding pipe is connected between the condensers and the air inlet of the air distribution apparatus. The controller controls the adjusting members to rotate to change opening sizes of the air outlets.

### BACKGROUND

1. Technical Field

The present disclosure relates to container data centers, and particularly to a container data center comprising a heat dissipation system.

2. Description of Related Art

Container data centers generally include a container and a row of server racks received in the container. An air conditioner can be used to generate cooling air, and the cooling air is introduced into the container by a guiding pipe for dissipating heat generated by the server racks. However, the pressure of the cooling air in the guiding pipe adjacent to the air outlet is greater than the pressure of the cooling air away from the air outlet, so temperatures of the server racks away from the air outlet of the guiding pipe are higher than temperatures of the server racks adjacent to the air outlet.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an assembled, isometric view of an embodiment of a container data center comprising a heat dissipation system with an air distribution apparatus.

FIG. 2 is an enlarged, isometric view of the air distribution apparatus of FIG. 1.

FIG. 3 is an inverted view of the air distribution apparatus of FIG. 2.

FIG. 4 is a partial exploded, isometric view of the air distribution apparatus of FIG. 3.

FIG. 5 is a block diagram of the heat dissipation system of FIG. 1.

FIG. 6 is a top plan view of FIG. 1 showing the container data center in a state of use.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

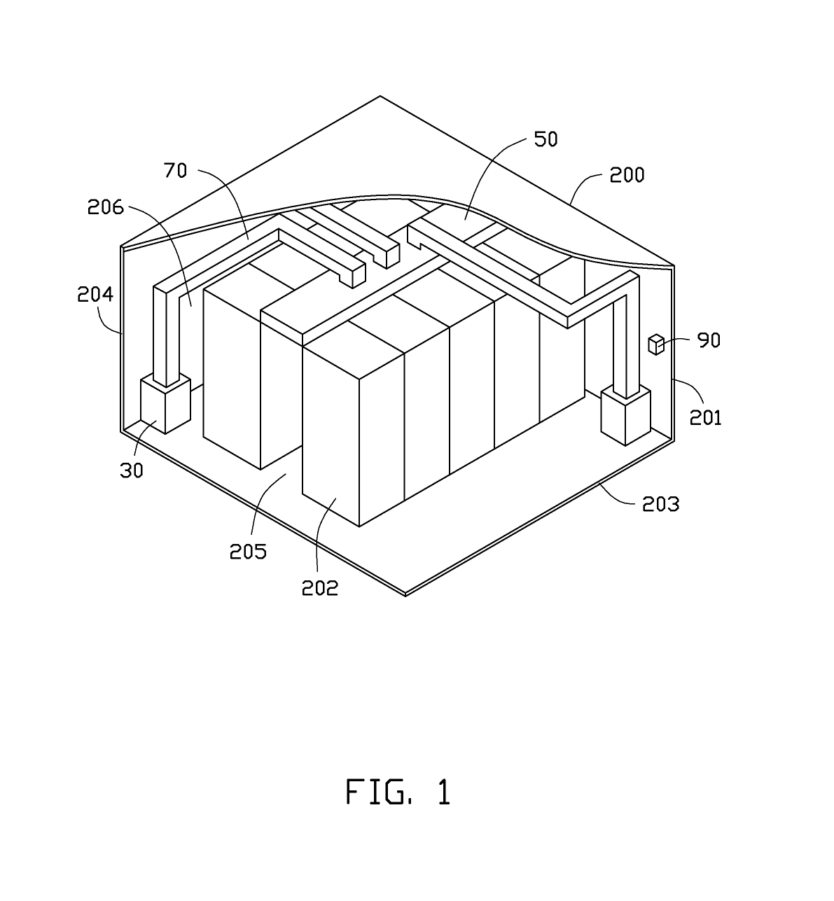

FIG. 1 shows an exemplary embodiment of a container data center 200. The container data center 200 comprises a container 201, two spaced rows of cabinet servers 202 received in the container 201, and a heat dissipation system. The container 201 comprises a bottom plate 203 and two side plates 204 (only one shown) connected to opposite sides of the bottom plate 203, respectively. The two rows of cabinet servers 202 are supported on the bottom plate 203 and substantially parallel to the side plates 204. The two rows of cabinet servers 202 cooperatively bound a cooling channel 205, and the two rows of cabinet servers 202 and the corresponding side plates 204 cooperatively bound two heat channels 206.

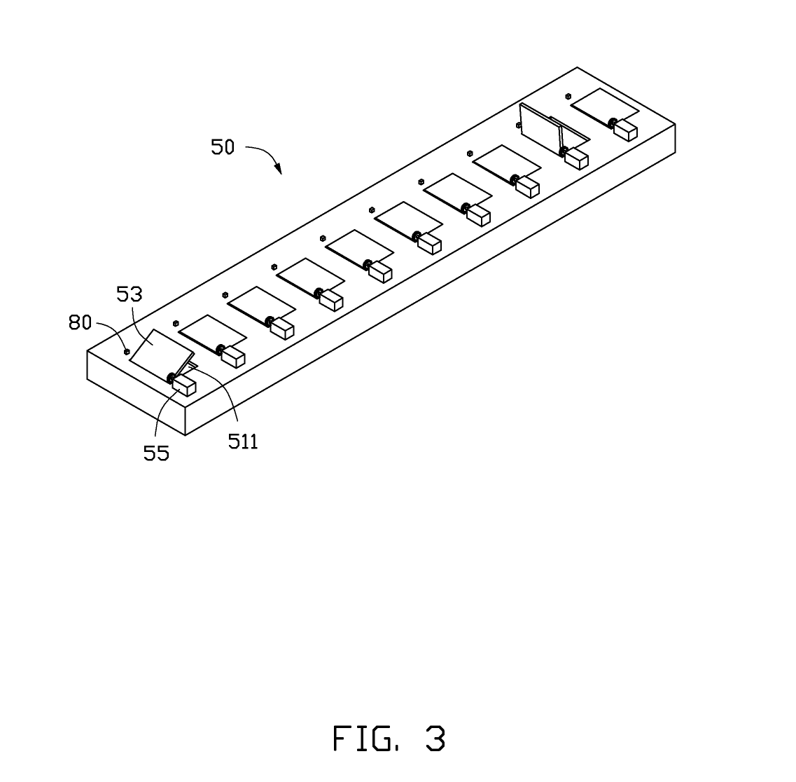

In one embodiment, the heat dissipation system comprises three condensers 30 located on the bottom plate 203, an air distribution apparatus 50 located above the cooling channel 205 and mounted between top sides of the two rows of cabinet servers 202, three pipes 70 corresponding to the three condensers 30, a plurality of temperature sensors 80 (shown in FIG. 3), and a controller 90. The three pipes 70 are connected between the three condensers 30 and the air distribution apparatus 50. The air distribution apparatus 50 blocks the top portion of the cooling channel 205.

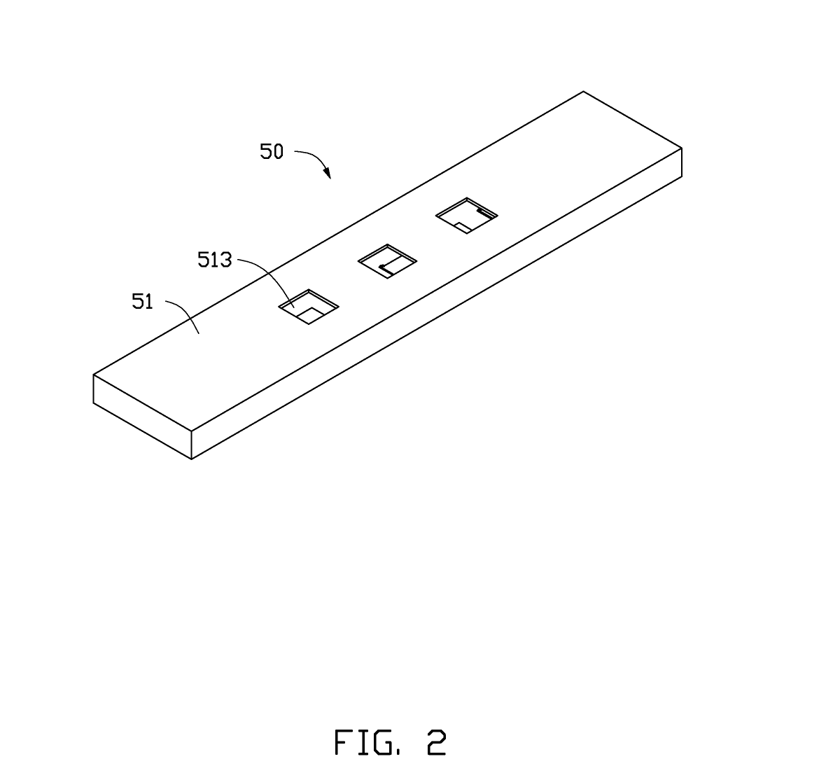

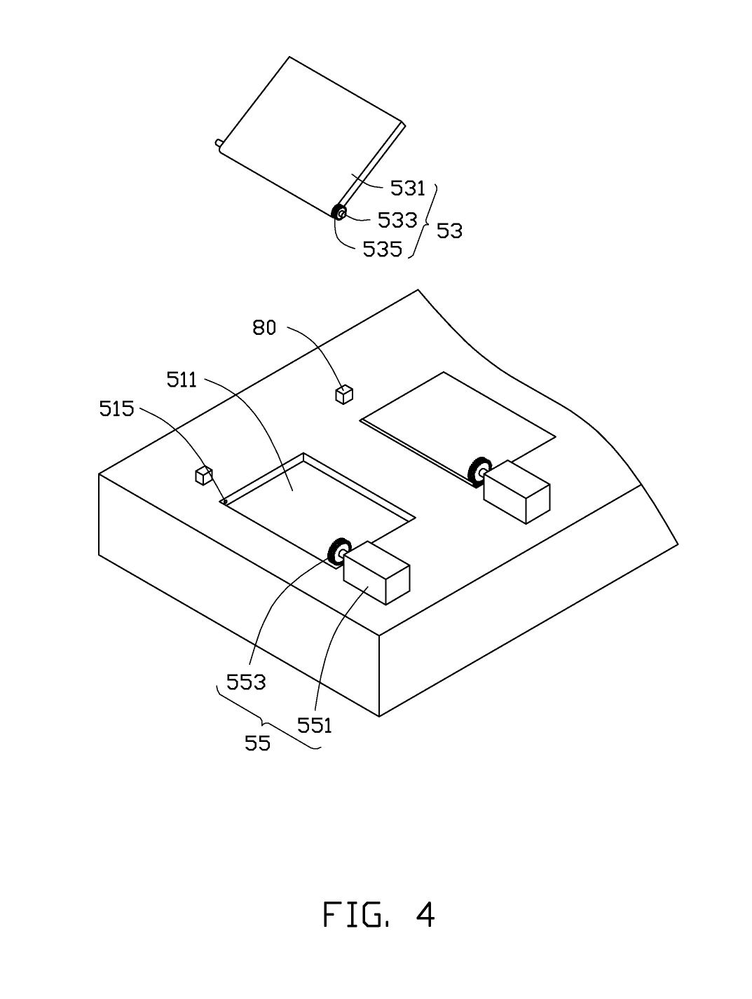

FIGS. 2-4 show that the air distribution apparatus 50 comprises a substantially rectangular distribution box 51, a plurality of adjusting members 53, and a plurality of motors 55 for driving corresponding adjusting members 53. The distribution box 51 is located at a top portion of the cooling channel 205 and mounted between the two rows of the cabinet servers 202. A top wall of the distribution box 51 defines three air inlets 513 communicating with an inner space of the distribution box 51, and a bottom wall of the distribution box 51 defines a plurality of air outlets 511 arranged along a lengthwise direction of the distribution box 51 and communicating with the inner space of the distribution box. First ends of the pipes 70 are connected to the condensers 30, and second ends of the pipes 70 are connected to the air inlets 513 of the air distribution apparatus 50. Each air outlet 511 is substantially rectangular, and two opposite sidewalls bounding the air outlet 511 each define a shaft hole 515. The shaft holes 511 face each other.

Each adjusting member 53 comprises a substantially rectangular shielding piece 531, two opposite shafts 533 extending out from two opposite sides of the shielding piece 531, respectively, and a gear 535 fitted about one of the shafts 533. Each shielding piece 531 is received in a corresponding air outlet 511 of the distribution box 51, and the shafts 533 are rotatably received in the corresponding shaft holes 515.

Each motor 55 comprises a main body 551 mounted to the bottom wall of the distribution box 51 and a drive gear 553 engaged with the gear 535 of the corresponding adjusting member 53. The main body 551 drives the drive gear 553 to rotate, and the drive gear 553 drives the gear 535 to rotate, thereby rotating the shielding piece 531 to open or shield the air outlet 511. Each motor 55 is electrically coupled to the controller 90.

The temperature sensors 80 are mounted on the bottom wall of the distribution box 51, adjacent to the corresponding air outlets 511. The temperature sensors 80 are electrically coupled to the controller 90.

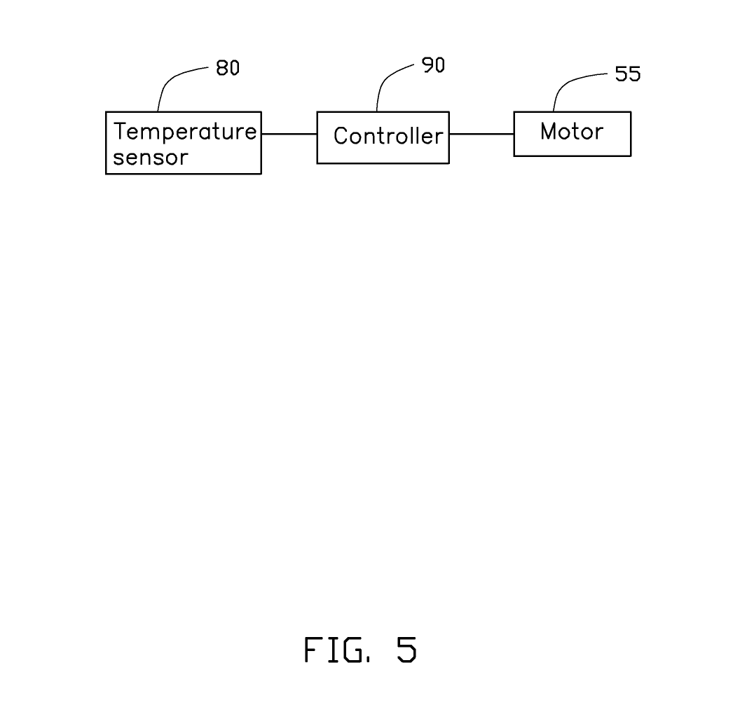

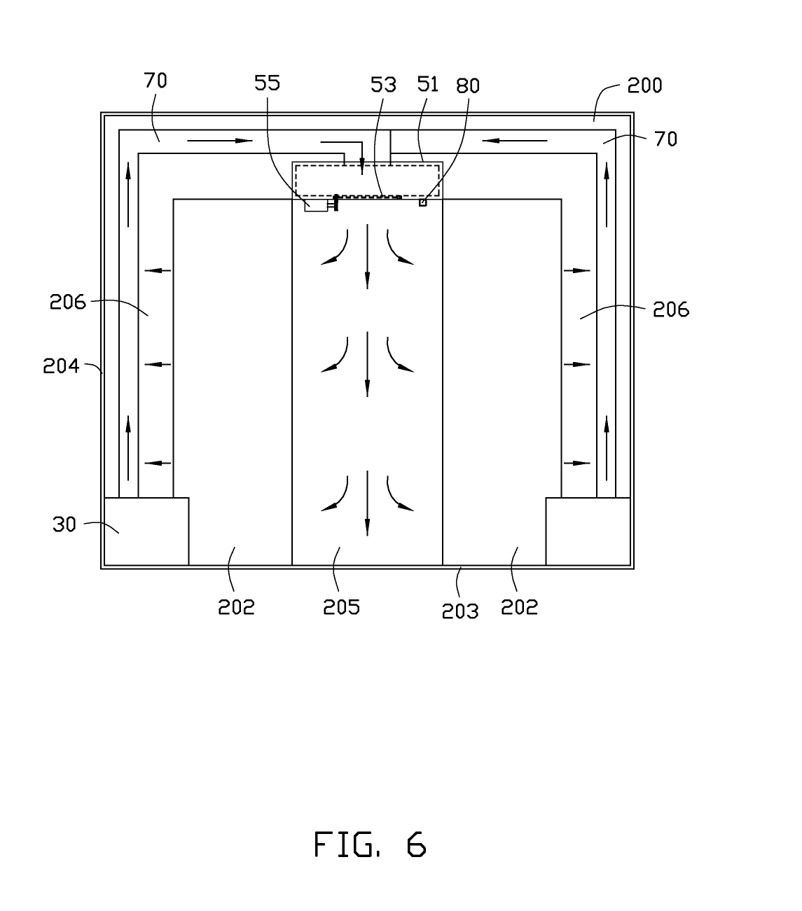

FIGS. 5 and 6 show that the cabinet servers 202 generate heat when in use. The condensers 30 generate cooling air, which flows through the pipes 70 into the air inlets 513. Thus, the cooling air flows into the distribution box 51. The cooling air flows into the cooling channel 205 through the air outlets 511. The heat of the cabinet servers 202 is transferred to the cooling air. Thus, the cooling air is heated. The heated air flows through the heat channels 206. The temperature sensors 80 measure a temperature of the air outlets 511. Each temperature sensor 80 outputs a signal corresponding to the sensed temperature to the controller 90. The sensed temperatures are compared by the controller 90. If the temperature of one of the air outlets 511 is greater than the temperature of the other air outlets 511, the controller 90 controls the corresponding motor 55 to operate to rotate the corresponding shielding piece 531 away from the bottom wall of the distribution box 51, thereby increasing an opening size of the air outlet 511 to increase airflow of the cooling air through the air outlet 511. If the temperature of one of the air outlets 511 is less than the temperature of the other air outlets 511, the controller 90 controls the corresponding motor 55 to operate to rotate the corresponding shielding piece 531 toward the bottom side of the distribution box 51, thereby decreasing the opening size of the corresponding air outlet 511 to decrease the airflow of the cooling air through the air outlet 511.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A heat dissipation system, comprising:
a condenser;
an air distribution apparatus comprising a distribution box and a plurality of adjusting members, wherein the distribution box defines an air inlet, and a plurality of air outlets arrayed along a lengthwise direction of the distribution box, the plurality of adjusting members is mounted to the distribution box to cover or uncover the plurality of air outlets;
a guiding pipe connected between the condenser and the air inlet of the air distribution apparatus, to guide cooling air from the condenser to the air inlet; and
a controller controlling the plurality of adjusting members to change opening sizes of the plurality of air outlets, thereby adjusting airflow flowing through the plurality of air outlets.

2. The heat dissipation system of claim 1, further comprising a plurality of temperature sensors located at the plurality of air outlets, wherein the plurality of temperature sensors is electrically coupled to the controller, the plurality of temperature sensors measures temperature of the plurality of air outlets, and each temperature sensor outputs the measured temperature to the controller, the temperature of the plurality of temperature sensors is compared by the controller.

3. The heat dissipation system of claim 2, wherein when the temperature of one of the plurality of temperature sensors is greater than the temperature of the other temperature sensors, the controller controls the corresponding adjusting member to rotate, the opening size of the air outlet is increased, to increase the airflow of the cooling air flowing through the air outlet.

4. The heat dissipation system of claim 2, wherein when the temperature of one of the plurality of temperature sensors is less than the temperature of the other temperature sensors, the controller controls the corresponding adjusting member to rotate, the opening size of the corresponding air outlet is decreased, to decrease the airflow of the cooling air flowing through the air outlet.

5. The heat dissipation system of claim 1, wherein the air distribution apparatus further comprises a plurality of motors driving the plurality of adjusting members, the plurality of motors is electrically coupled to the controller.

6. The heat dissipation system of claim 5, wherein each adjusting member comprises a shielding piece to cover or uncover the corresponding air outlet, two opposite shafts extending out from the shielding piece and connected to the distribution box, and a gear fitted about one of the shafts, each motor comprises a drive gear engaged with the gear of the corresponding adjusting member.

7. A container data center, comprising:
a container;
two spaced rows of cabinet servers received in the container;
a condenser;
an air distribution apparatus comprising a distribution box located at tops of the cabinet servers and a plurality of adjusting members, wherein the distribution box is mounted between the rows of servers, the distribution box defines an air inlet, and a plurality of air outlets arrayed along a lengthwise direction of the distribution box, the plurality of adjusting members is mounted to the distribution box to cover or uncover the plurality of air outlets;
a guiding pipe connected between the condenser and the air inlet of the air distribution apparatus, to guide cooling air from the condenser to the air inlet; and
a controller controlling the plurality of adjusting members, to change opening sizes of the plurality of air outlets, thereby adjusting airflow flowing through the plurality of air outlets.

8. The container data center of claim 7, wherein the two rows cabinet servers cooperatively bound a cooling channel, the distribution box is located above the cooling channel, and the plurality of air outlets faces the cooling channel.

9. The container data center of claim 7, wherein the container comprises a bottom plate and two side plates extending up from two opposite sides of the bottom plate, the two rows of cabinet servers are supported on the bottom plate and parallel to the side plates, the two rows of cabinet servers and the corresponding side plates cooperatively bound two heat channels.

10. The container data center of claim 7, further comprising a plurality of temperature sensors located at the plurality of air outlets, wherein the plurality of temperature sensors is electrically coupled to the controller, the plurality of temperature sensors measures temperature of the plurality of air outlets, and each temperature sensor outputs the measured temperature to the controller, the temperature of the plurality of temperature sensors is compared by the controller.

11. The container data center of claim 10, wherein when the temperature of one of the plurality of temperature sensors is greater than the temperature of the other temperature sensors, the controller controls the corresponding adjusting member to rotate, the opening size of the air outlet is increased, to increase airflow of the cooling air flowing through the air outlet.

12. The container data center of claim 10, wherein when the temperature of one of the plurality of temperature sensors is less than the temperature of the other temperature sensors, the controller controls the corresponding adjusting member to rotate, the opening size of the corresponding air outlet is decreased, to increase the airflow of the cooling air flowing through the air outlet.

13. The container data center of claim 7, wherein the air distribution apparatus further comprises a plurality of motors driving the plurality of adjusting members, the plurality of motors is electrically coupled to the controller.

14. The container data center of claim 13, wherein each adjusting member comprises a shielding piece to cover or uncover the corresponding air outlet, two opposite shafts extending out from the shielding piece and connected to the distribution box, and a gear fitted about one of the shafts, each motor comprises a drive gear engaged with the gear of the corresponding adjusting member.
